(19) United States
(12) Patent Application Publication
(10) Pub. No.: US 2021/0348263 A1
(43) Pub. Date: Nov. 11, 2021

(54) DEPOSITION APPARATUS AND DEPOSITION METHOD

(71) Applicant: ULVAC, INC., Chigasaki-shi, Kanagawa (JP)

(72) Inventors: Shuji KODAIRA, Chigasaki-shi, Kanagawa (JP); Teppei TAKAHASHI, Chigasaki-shi, Kanagawa (JP); Takahiro TOBIISHI, Chigasaki-shi, Kanagawa (JP); Norifumi YAMAMURA, Chigasaki-shi, Kanagawa (JP); Hiroaki KATAGIRI, Chigasaki-shi, Kanagawa (JP); Junya KUBO, Chigasaki-shi, Kanagawa (JP); Masaaki SUZUKI, Chigasaki-shi, Kanagawa (JP)

(21) Appl. No.: 17/278,083

(22) PCT Filed: Oct. 30, 2019
(86) PCT No.: PCT/JP2019/042617

§ 371 Date: Mar. 19, 2021

(30) Foreign Application Priority Data
Dec. 28, 2018 (JP) 2018-247792

(51) Int. Cl. C23C 14/50; C23C 14/34

(52) U.S. Cl. CPC C23C 14/505; C23C 14/3464; C23C 14/3407

(57) ABSTRACT

[Object] A film is deposited on a substrate with high productivity and more uniform film thickness distribution.

[Solving Means] In a deposition apparatus, a substrate holder supports at least one substrate facing a first target, rotates around a first central axis, and is configured such that the substrate is rotatable around a second central axis deviated from the first central axis. A vacuum chamber houses the first target and the substrate holder. A power source supplies discharge power to the first target. A gas supply mechanism supplies a discharge gas to the vacuum chamber. Relational expressions of Ds+Dt≥H, A≥R, and H≥R are satisfied, Ds being a distance between the first central axis and the second central axis in a direction perpendicular to the first central axis, Dt being a distance between the first central axis and a center of the first target in a direction perpendicular to the first central axis, R being a radius of the first target, H being a distance between the first target and the substrate in a direction of the first central axis, A being an absolute value of a difference between Ds and Dt.

### TECHNICAL FIELD

The present invention relates to a deposition apparatus and a deposition method.

### BACKGROUND ART

In recent years, as a deposition apparatus, there is provided an apparatus that forms a film on a substrate while causing the substrate supported by a substrate holder to rotate and causing the substrate holder facing a sputtering target to rotate in order to improve the film thickness distribution of the film formed on the substrate (see, for example, Patent Literature 1).

### CITATION LIST

### Patent Literature

Patent Literature 1: Japanese Patent Application Laid-open No. 2013-147677

### DISCLOSURE OF INVENTION

### Technical Problem

In such an apparatus, more stringent specifications for film thickness distribution as well as high productivity are required in some cases.

In view of the circumstances as described above, it is an object of the present invention to provide a deposition apparatus and a deposition method that are capable of depositing a film on a substrate with high productivity and more uniform film thickness distribution.

### Solution to Problem

In order to achieve the above-mentioned object, a deposition apparatus according to an embodiment of the present invention includes: a first target; a substrate holder; a vacuum chamber; a power source; and a gas supply mechanism.

The substrate holder supports at least one substrate facing the first target, rotates around a first central axis, and is configured such that the substrate is rotatable around a second central axis deviated from the first central axis.

The vacuum chamber houses the first target and the substrate holder.

The power source supplies discharge power to the first target.

The gas supply mechanism supplies a discharge gas to the vacuum chamber.

Relational expressions of Ds+Dt≥H, A≥R, and H≥R are satisfied, Ds being a distance between the first central axis and the second central axis in a direction perpendicular to the first central axis, Dt being a distance between the first central axis and a center of the first target in a direction perpendicular to the first central axis, R being a radius of the first target, H being a distance between the first target and the substrate in a direction of the first central axis, A being an absolute value of a difference between Ds and Dt.

In accordance with such a deposition apparatus, since deposition is performed under the condition that the first target, the substrate holder, and the substrate satisfy the above-mentioned relational expressions, the productivity is high and a film is formed on the substrate with more uniform film thickness distribution.

The deposition apparatus may further include a second target juxtaposed with the first target in a direction perpendicular to the first central axis.

Relational expressions of Ds+Dt′≥H′, A′≥R′, and H′≥R′ are satisfied, Dt′ being a distance between the first central axis and a center of the second target in a direction perpendicular to the first central axis, R′ being a radius of the second target, H′ being a distance between the second target and the substrate in the direction of the first central axis, A′ being an absolute value of a difference between Ds and Dt′.

In accordance with such a deposition apparatus, since deposition is performed under the condition that the second target, the substrate holder, and the substrate in addition to the first target satisfy the above-mentioned relational expressions, the productivity is high and a film is formed on the substrate with more uniform film thickness distribution.

In the deposition apparatus, a sign of the difference between Ds and Dt may be reversed from a sign of the difference between Ds and Dt′.

In accordance with such a deposition apparatus, since the second target is used in addition to the first target, the productivity is high and a film is formed on the substrate with more uniform film thickness distribution.

In the deposition apparatus, the power source may supply, to the first target, electric power different from that for the second target.

In accordance with such a deposition apparatus, since the feed power is adjusted for each of the first target and the second target, a film is formed on the substrate with more uniform film thickness distribution.

In the deposition apparatus, one of normal lines to a surface of the substrate, a surface of the first target, and a surface of the second target may intersect the first central axis.

In accordance with such a deposition apparatus, since one of normal lines to a surface of the substrate, a surface of the first target, and a surface of the second target is adjusted to intersect the first central axis, a film is formed on the substrate with more uniform film thickness distribution.

In order to achieve the above-mentioned object, a deposition apparatus according to an embodiment of the present invention includes: a plurality of targets; a substrate holder; a vacuum chamber; a power source; and a gas supply mechanism.

The substrate holder supports at least one substrate facing the plurality of targets, rotates around a first central axis, and is configured such that the substrate is rotatable around a second central axis deviated from the first central axis.

The vacuum chamber houses the plurality of targets and the substrate holder.

The power source supplies discharge power to the plurality of targets.

The gas supply mechanism supplies a discharge gas to the vacuum chamber.

The plurality of targets is juxtaposed with each other in a direction perpendicular to the first central axis.

Relational expressions of Ds+Dt≥H, A≥R, and H≥R are satisfied, Ds being a distance between the first central axis and the second central axis in a direction perpendicular to the first central axis, Dt being a distance between the first central axis and a center of one of the plurality of targets in a direction perpendicular to the first central axis, R being a radius of the one target, H being a distance between the plurality of targets and the substrate in a direction of the first central axis, A being an absolute value of a difference between Ds and Dt.

In accordance with such a deposition apparatus, since deposition is performed under the condition that the first target, the substrate holder, and the plurality of substrates satisfy the above-mentioned relational expressions, the productivity is high and a film is formed on the substrate with more uniform film thickness distribution.

In order to achieve the above-mentioned object, a deposition method according to an embodiment of the present invention includes: supporting at least one substrate on a substrate holder that is housed in a vacuum chamber and rotates around a first central axis, the substrate supported by the substrate holder rotating around a second central axis deviated from the first central axis.

A discharge gas is supplied to the vacuum chamber.

Discharge power is supplied to a first target that faces the substrate holder and is housed in the vacuum chamber.

Deposition is performed on the substrate under a condition that relational expressions of Ds+Dt≥H, A≥R, and H≥R are satisfied, Ds being a distance between the first central axis and the second central axis in a direction perpendicular to the first central axis, Dt being a distance between the first central axis and a center of the first target in a direction perpendicular to the first central axis, R being a radius of the first target, H being a distance between the first target and the substrate in a direction of the first central axis, A being an absolute value of a difference between Ds and Dt.

In accordance with such a deposition method, deposition is performed under the condition that the first target, the substrate holder, and the substrate satisfy the above-mentioned relational expressions, the productivity is high and a film is formed on the substrate with more uniform film thickness distribution.

In the deposition method, a second target may be juxtaposed with the first target in a direction perpendicular to the first central axis in the vacuum chamber, and discharge power may be supplied to the second target.

Deposition is performed on the substrate under a condition that relational expressions of Ds+Dt′≥H′, A′≥R′, and H′≥R′ are satisfied, Dt′ being a distance between the first central axis and a center of the second target in a direction perpendicular to the first central axis, R′ being a radius of the second target, H′ being a distance between the second target and the substrate in the direction of the first central axis, A′ being an absolute value of a difference between Ds and Dt′.

In accordance with such a deposition apparatus, since deposition is performed under the condition that the second target, the substrate holder, and the substrate in addition to the first target satisfy the above-mentioned relational expressions, the productivity is high and a film is formed on the substrate with more uniform film thickness distribution.

### Advantageous Effects of Invention

As described above, in accordance with the present invention, a deposition apparatus and a deposition method that are capable of depositing a film on a substrate with high productivity and more uniform film thickness distribution are provided.

### BRIEF DESCRIPTION OF DRAWINGS

FIG. 1 Part (a) of FIG. 1 is a schematic top view of a deposition apparatus according to this embodiment. Part (b) of FIG. 1 is a schematic cross-sectional view of the deposition apparatus according to this embodiment.

FIG. 2 Part (a) of FIG. 2 is a schematic top view of a deposition apparatus according to a modified example 1 of this embodiment. Part (b) of FIG. 2 is a schematic cross-sectional view of the deposition apparatus according to this embodiment.

FIG. 3 is a schematic diagram of film thickness distribution of a film formed on a substrate in the case of using multi-targets.

FIG. 4 is a schematic top view of a deposition apparatus according to a modified example 2 of this embodiment.

FIG. 5 is a schematic cross-sectional view of a deposition apparatus according to a modified example 3 of this embodiment.

### MODE(S) FOR CARRYING OUT THE INVENTION

Hereinafter, an embodiment of the present invention will be described with reference to the drawings. In each of the drawings, XYZ axis coordinates are introduced in some cases. In addition, the same members or members having the same function may be denoted by the same reference symbols, and the description thereof may be appropriately omitted after the description of the members.

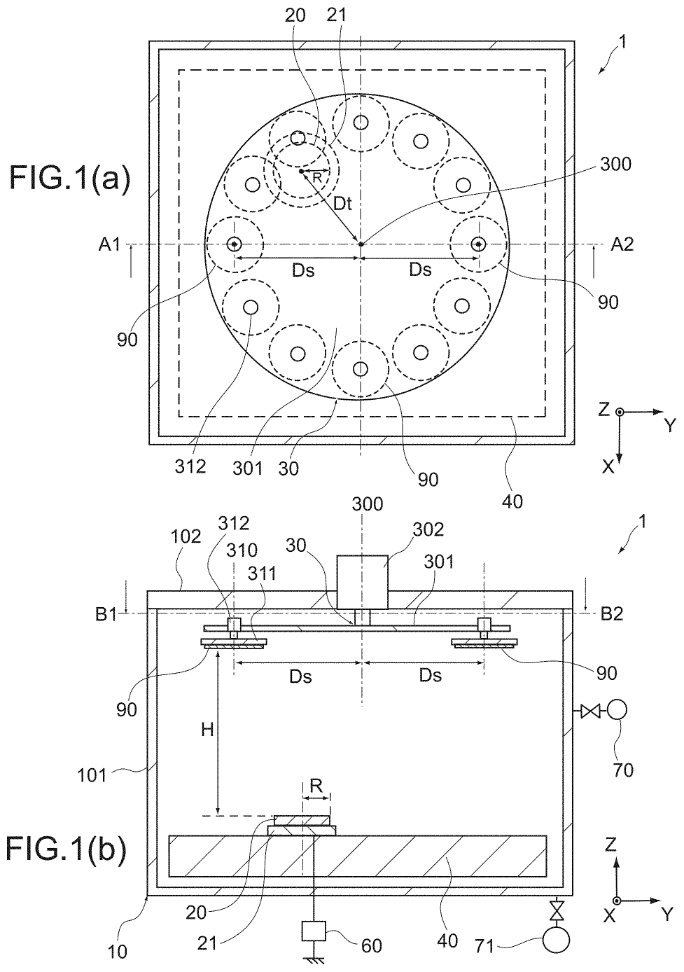

Part (a) of FIG. 1 is a schematic top view of a deposition apparatus according to this embodiment. Part (b) of FIG. 1 is a schematic cross-sectional view of the deposition apparatus according to this embodiment. In Part (a) of FIG. 1, a cross section along the line B1-B2 of Part (b) of FIG. 1 is shown. In Part (b) of FIG. 1, a cross section along the line A1-A2 of Part (a) of FIG. 1 is shown.

A deposition apparatus 1 is a so-called deposition-up type sputtering apparatus. The deposition apparatus 1 includes a vacuum chamber 10, a target 20 (first target), a substrate holder 30, a support stand 40, a power source 60, a gas source 70, and an exhaust mechanism 71. On the substrate holder 30, not only one substrate but also a plurality of substrates 90 can be placed. The substrate 90 is, for example, a semiconducting wafer, a glass substrate, or a quartz substrate.

The vacuum chamber 10 is a chamber capable of maintaining a reduced pressure. The vacuum chamber 10 includes a chamber body 101 and a lid portion 102. The lid portion 102 covers the chamber body 101 and tightly blocks the chamber body 101. In the case where the vacuum chamber 10 is viewed from above in the Z-axis direction, the outer shape of the vacuum chamber 10 is, for example, a rectangular shape. The vacuum chamber 10 houses the target 20, the substrate holder 30, the support stand 40, and the like.

The gas source 70 is attached to the vacuum chamber 10. The gas source 70 supplies a plasma-discharging gas into the vacuum chamber 10. The gas is, for example, an inert gas (Ar, Ne, He, or the like), oxygen (O), or nitrogen (N). The gas source 70 may be provided with a gas flow meter for adjusting the gas flow rate. Further, the vacuum chamber 10 may also be provided with a pressure gauge for measuring the inner pressure.

Further, the exhaust mechanism 71 such as a vacuum pump is connected to the vacuum chamber 10. This exhaust mechanism 71 evacuates the atmosphere of the vacuum chamber 10 and maintains the vacuum. Further, the gas introduced into the vacuum chamber 10 is exhausted by the exhaust mechanism 71, and the vacuum chamber 10 is maintained at a predetermined pressure.

The target 20 (sputtering target) is bonded to a backing plate 21 formed of a metal. The planar shapes of the target 20 and the backing plate 21 are, for example, circular. The target 20 is fixed to the support stand 40 located at the bottom of the vacuum chamber 10. Further, a magnet (not shown) may be disposed on the back surface of the target 20. This realizes magnetron sputtering. The front surface (surface to be sputtered) of the target 20 faces the substrate holder 30.

The material of the target is appropriately selected in accordance with the composition of the layer formed in the substrate 90. The material of the target is not particularly limited, and may be, for example, silicon (Si), niobium (Nb), or tantalum (Ta).

The substrate holder 30 includes a rotating plate 301, a rotating mechanism 302, a substrate support 311, and a rotating mechanism 312. The substrate holder 30 faces the target 20.

The rotating plate 301 has a circular shape in its planar shape. The rotating plate 301 rotates around a central axis 300 of the rotating plate 301 by the rotating mechanism 302. Further, the rotating plate 301 is provided with a plurality of substrate supports 311. The plurality of substrate supports 311 faces the target 20.

For example, in the example shown in Part (a) of FIG. 1, 12 substrate supports 311 are disposed around the central axis 300 (first central axis) of the substrate holder 30. The planar shape of the substrate support 311 is designed to match the planar shape of the substrate 90 and is, for example, circular. Further, the distances of the plurality of substrate supports 311 from the central axis 300 are the same.

Further, the rotating plate 301 is provided with the rotating mechanism 312 that causes the substrate support 311 to rotate (turn on its own axis). This rotating mechanism 312 causes the substrate support 311 to rotate around a central axis 310 deviated from the central axis 300.

By providing the substrate holder 30 with the plurality of substrate supports 311, the substrate holder 30 is capable of supporting one or more substrates 90. The substrate 90 supported by the substrate support 311 faces the target 20. Further, in the case where the substrate 90 is supported by the substrate support 311, the central axis 310 is also a central axis around which the substrate 90 rotates. That is, the substrate 90 rotates around the central axis 310 by the rotating mechanism 312.

Further, when the plurality of substrates 90 is supported by the substrate holder 30, each of the plurality of substrates 90 is located at the same distance from the central axis 300 of the substrate holder 30. As a result, when the substrate holder 30 rotates around the central axis 300, each of the plurality of substrates 90 revolves around the central axis 300. At this time, each of the plurality of substrates 90 passes through the same path above the target 20.

The power source 60 supplies electric power to the target 20 via the backing plate 21. The electric power is DC power, pulsed DC power, RF power, or the like. For example, in the case where the DC power is supplied to the target 20, the target 20 is a cathode and the vacuum chamber 10 or the like is an anode (or a ground). Further, when the power source 60 is an RF power source, a matching circuit (not shown) may be provided between the power source 60 and the target 20.

Note that a shutter mechanism for closing a space between the target 20 and the substrate 90 may be provided on the target 20.

Further, the deposition apparatus 1 may be provided with an oxygen plasma source that exposes a film formed on the substrate 90 to oxygen plasma and oxidizes the film to form an oxide film.

In the deposition apparatus 1, the substrate holder 30, the target 20, and the substrate 90 are disposed to satisfy relational expressions of

Ds+Dt≥H Expression (1)

A≥R Expression (2)

H≥R Expression (3)

Ds being a distance between the central axis 300 and the central axis 310 in a direction perpendicular to the central axis 300, Dt being a distance between the central axis 300 and a center of the target 20 in a direction perpendicular the central axis 300, R being a radius of the target 20, H being a distance between the target 20 and the substrate 90 in a direction of the central axis 300, A being an absolute value of a difference (Ds−Dt) between Ds and Dt.

For example, in the vacuum chamber 10, at least one substrate 90 is supported by the substrate holder 30 and revolves around the central axis 300 while rotating around the central axis 310. At this time, the angular velocity at which the substrate 90 rotates around the central axis 310 is set faster than the angular velocity at which the substrate 90 revolves around the central axis 300.

Further, a discharge gas such as Ar is supplied to the vacuum chamber 10 from the gas source 70, and discharge power is supplied to the target 20 from the power source 60. As a result, the target 20 is sputtered by the plasma, and a film is formed on the substrate 90 under the condition that the relational expressions (1) to (3) are satisfied.

Here, the amount of sputtered particles flying from the target 20 depends on the emission angle at which the sputtered particles jump out from the target 20. For example, the amount of sputtered particles is the most in the direction of the normal line of the target 20 and gradually decreases as it is deviated from the normal line.

Even if sputtered particles jump out from the target 20 with such emission angular distribution, the thickness of the film formed on the substrate 90 becomes more uniform by performing sputtering deposition on the substrate 90 under the condition that the relational expressions (1) to (3) are satisfied. Further, since the plurality of substrates 90 can be held by the substrate holder 30, sputtering deposition can be performed on the plurality of substrates 90 in one batch, and the productivity is improved.

### Modified Example 1

Further, the number of targets 20 is not necessarily one, and a plurality of targets (multi-targets) may be used.

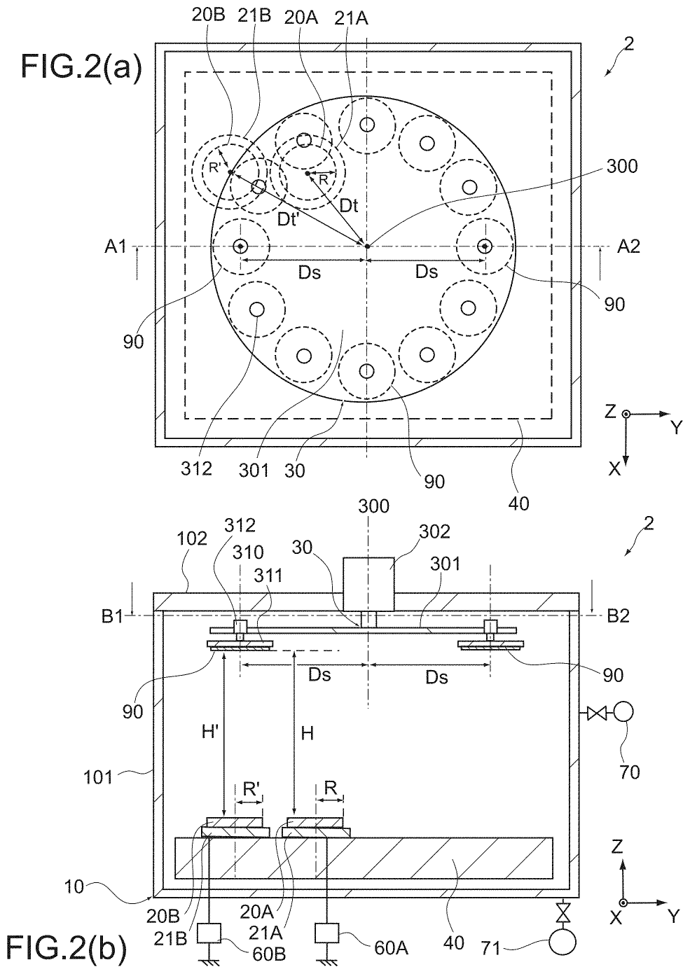

Part (a) of FIG. 2 is a schematic top view of a deposition apparatus according to a modified example 1 of this embodiment. Part (b) of FIG. 2 is a schematic cross-sectional view of the deposition apparatus according to this embodiment. In Part (a) of FIG. 2, a cross section along the line B1-B2 of Part (b) of FIG. 2 is shown. In Part (b) of FIG. 2, a cross section along the line A1-A2 of Part (a) of FIG. 2 is shown.

In the case where the above-mentioned target 20 is a target 20A, a deposition apparatus 2 includes a target 20B (second target) juxtaposed with the target 20A in a direction perpendicular to the central axis 300.

The target 20B is bonded to a backing plate 21B formed of a metal. The planar shapes of the target 20B and the backing plate 21B are, for example, circular. The target 20B is fixed to the support stand 40. Further, a magnet (not shown) may be disposed on the back surface of the target 20B. The front surface (surface to be sputtered) of the target 20B faces the substrate holder 30.

The power source 60B supplies electric power to the target 20B via the backing plate 21B. Note that the above-mentioned backing plate 21 corresponds to a backing plate 21A, and the above-mentioned power source 60 corresponds to a power source 60A.

In the examples of Parts (a) and (b) of FIG. 2, the direction in which the targets 20A and 20B is parallel to a part of the inner wall of the vacuum chamber 10. For example, the targets 20A and 20B are disposed such that when a line is drawn from the central axis 300 to an arbitrary position on the front surface of the target 20B, a part of the drawn line overlaps the front surface of the target 20A.

The target 20A is located on the side of the central axis 300 of the line through which the substrate 90 passes, and the target 20B is located on the side of the vacuum chamber 10 of the line. In the case where the deposition apparatus 2 is viewed from above in the Z-axis direction, the substrate 90 moves (revolves) around the central axis 300 while overlapping both the targets 20A and 20B. Note that the direction in which the targets 20A and 20B are disposed is not limited to the Y-axis direction, and the targets 20A and 20B may be disposed in a direction intersecting the Y-axis direction.

Further, in the deposition apparatus 2, the substrate holder 30, the targets 20A and 20B, and the substrate 90 are disposed to satisfy relational expressions of

Ds+Dt′≥H′ Expression (4)

A′≥R′ Expression (5)

H′≥R′ Expression (6)

in addition to the relational expressions (1) to (3), Dt′ being a distance between the central axis 300 and a center of the target 20B in a direction perpendicular to the central axis 300, R′ being a radius of the target 20B, H′ being a distance between the target 20B and the substrate 90 in a direction of the central axis 300, A′ being an absolute value of a difference (Ds-Dt′) between Ds and Dt′. H′ is substantially the same as H. Further, the sign of the difference between Ds and Dt is reversed from the sign of the difference between Ds and Dt′. For example, in the case where the sign of Ds-Dt′ is negative, the sign of Ds-Dt is positive.

Discharge power is supplied from the power source 60B to the target 20B. As a result, the target 20B is sputtered by plasma in addition to the target 20A, and a film is formed on the substrate 90 under the condition that the relational expressions (1) to (6) are satisfied. Note that the electric power supplied to the target 20A by the power source 60A and the electric power supplied to the target 20B by the power source 60B may be different from each other. For example, the electric power supplied by the power source 60B is set higher than the electric power supplied by the power source 60A. For example, the electric power supplied by the power source 60B is set to approximately twice the electric power supplied by the power source 60A.

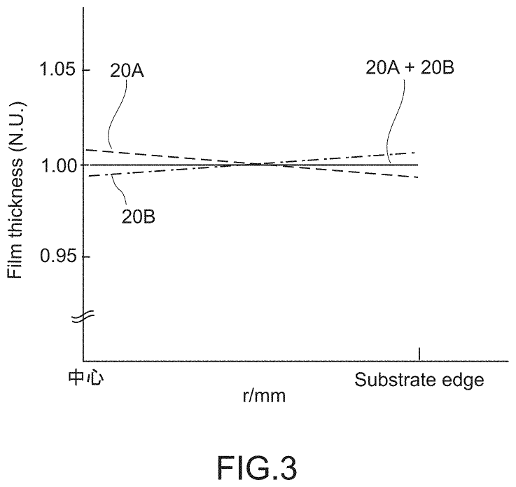

FIG. 3 is a schematic diagram of film thickness distribution of a film formed on a substrate in the case where multi-targets are used. The horizontal axis represents a distance r from the center of the substrate 90, and the vertical axis represents the film thickness (standard value).

By using the deposition apparatus 2, film thickness distribution generated in the case where only the target 20A is used is corrected by film thickness distribution generated in the case where the target 20B is used, and the thickness of the film formed on the substrate 90 becomes more uniform.

For example, assumption is made that the film thickness distribution generated in the case where the target 20A is used is film thickness distribution downward from the center of the substrate 90 toward the substrate edge. In this case, in the case where the target 20B further from the central axis 300 than the target 20A is used, the film thickness distribution is film thickness distribution upward from the center of the substrate 90 toward the substrate edge.

Therefore, when the target 20A and the target 20B are used, the film thickness distribution generated in the case where only the target 20A is used is corrected by the film thickness distribution generated in the case where the target 20B is used, and the thickness of the film formed on the substrate 90 becomes more uniform. In FIG. 3, this thickness is shown as 20A+20B.

### Modified Example 2

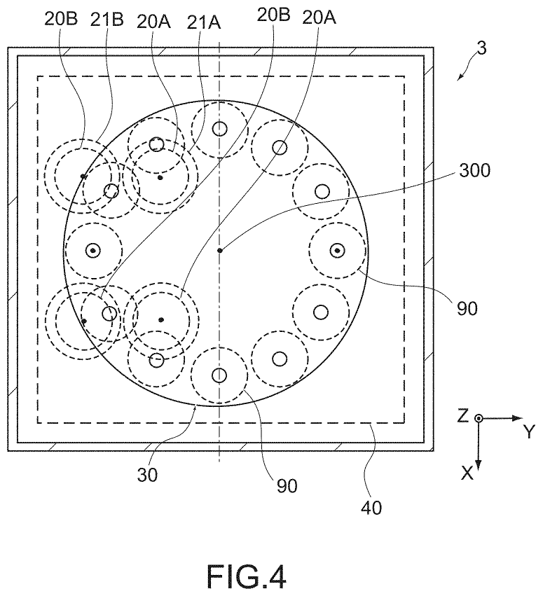

FIG. 4 is a schematic top view of a deposition apparatus according to a modified example 2 of this embodiment. FIG. 4 corresponds to the cross section along the line B1-B2 of Part (b) of FIG. 1.

The number of sets of the targets 20A and 20B fixed to the support stand 40 is not limited to one. For example, a deposition apparatus 3 includes two sets of the targets 20A and 20B. For example, a set of the targets 20A and 20B is disposed in a direction perpendicular to the direction in which a different set of the targets 20A and 20B is disposed, and the directions in which the sets of the targets 20A and 20B are disposed are parallel to each other.

In accordance with such a deposition apparatus 3, the film thickness distribution generated in the case where a set of the targets 20A and 20B is used is corrected by the film thickness distribution generated in the case where a different set of the targets 20A and 20B is used, so that the thickness of the film formed on the substrate 90 becomes more uniform. In addition, by changing the target material for each set, it is possible to alternately stack films in which materials are mixed or films in which materials differ from each other.

### Modified Example 3

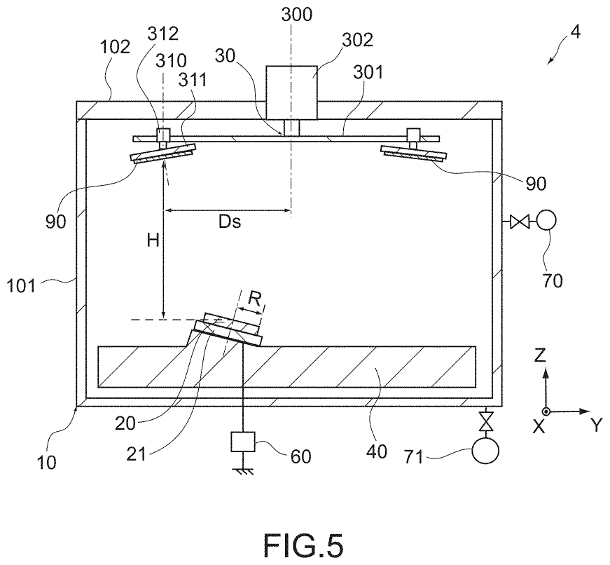

FIG. 5 is a schematic cross-sectional view of a deposition apparatus according to a modified example 3 of this embodiment.

In a deposition apparatus 4, one of normal lines to the front surface of the substrate 90 and the front surface of the target 20 intersects the central axis 300. For example, the respective normal lines are inclined toward the central axis 300. One of the normal lines to the front surface of the target 20A and the front surface of the target 20B may intersect the central axis 300.

In accordance with such a deposition apparatus 4, since one of the normal lines to the front surface of the substrate 90, the front surface of the target 20, and the front surface of each of the targets 20A and 20B is adjusted so as to intersect the central axis 300, a film is formed on the substrate 90 with more uniform film thickness distribution.

### EXAMPLE

This embodiment will be specifically described by way of the following Examples. The scope of this embodiment is not limited to the Examples shown below.

Table 1 shows the conditions and results in Examples 1 to 3 and Comparative Examples 1 and 2.

In Examples 1 to 3 and Comparative Examples 1 and 2, a Si wafer substrate with a diameter of approximately 300 mm was used as the substrate 90. The film thickness distribution (%) was defined as the value expressed as a percentage of the expression of ±(Dmax−Dmin)/(Dmax+Dmin), Dmax being the maximum film thickness of the film formed on the Si wafer substrate, Dmin being the minimum film thickness. The target value of the film thickness distribution is set to, for example, −1% or more and 1% or less. The diameter of each of the targets was set to 290 mm. The discharge pressure was 1.5 Pa. As the discharge power, DC power was used.

Further, in the case of multi-targets, two targets of the target 20A and the target 20B are used. The ratio (power ratio) of the electric power input to each of the targets was defined by the expression of P_{20B}/(P_{20A}+P_{20B}), P_{20A} being the electric power supplied to the target 20A, P_{20B} being the electric power supplied to the target 20B.

Details of the conditions in the respective Examples and Comparative Examples are as follows.

### Example 1

Material of the target 20A: Si

Discharge gas: Ar/O₂

Film: SiO₂ film

### Example 2

Material of the target 20A: Si

Discharge gas: Ar/O₂

Material of the target 20B: Nb

Discharge gas: Ar/O₂

Film: Stacked film of an SiO₂ film and an NbO₂ film

Power ratio: 0.67

### Example 2

Material of the target 20A: Si

Discharge gas: Ar/O₂

Material of the target 20B: Nb

Discharge gas: Ar/O₂

Film: Stacked film of an SiO₂ film and an NbO₂ film

Power ratio: 0.75

### Comparative Example 1

Material of the target 20A: Si

Discharge gas: Ar/O₂

Film: SiO₂ film

### Comparative Example 2

Material of the target 20A: Si

Discharge gas: Ar/O₂

Film: SiO₂ film

In Comparative Example 1, the expression (1) is satisfied, but the expression (2) is not satisfied because A is 100 mm and R is 145 mm. At this time, the film thickness distribution was ±6.9%. Further, in Comparative Example 2, the expression (1) is satisfied, but the expression (3) is not satisfied because H is 100 mm and R is 145 mm. At this time, the film thickness distribution was ±3.1%. Therefore, it was found that it was necessary to satisfy the expressions (2) and (3) in addition to the expression (1).

Meanwhile, in Examples 1 to 3, the expressions (1) to (6) are satisfied. For example, in Example 1 in which only the target 20A is used, the film thickness distribution was ±0.5%, which fell within the range of −1% or more and 1% or less. Further, in Example 2 in which the targets 20A and 20B are used, the film thickness distribution was ±0.27%, and film thickness distribution better than that obtained in Example 1 was obtained. Further, in Example 3, the electric power input to the target 20B was increased more than that in Example 2. In this case, the film thickness distribution was ±0.18%, and the film thickness distribution was better than that in Example 2.

TABLE 1
Unit: mm

| | | | | | A | | | | | A′ | | |
|---|---|---|---|---|---|---|---|---|---|---|---|---|
| | Ds | Dt | Ds + Dt | H | \| Ds − Dt \| | R | Dt′ | Ds + Dt′ | H′ | \| Ds − Dt′ \| | R′ | % |
| Example 1 | 600 | 450 | 1050 | 150 | 150 | 145 | — | — | — | — | — | ±0.5 |
| Example 2 | 600 | 450 | 1050 | 250 | 150 | 145 | 800 | 1400 | 250 | 200 | 145 | ±0.27 |
| Example 3 | 600 | 450 | 1050 | 250 | 150 | 145 | 800 | 1400 | 250 | 200 | 145 | ±0.18 |
| Comparative | 550 | 450 | 1000 | 150 | 100 | 145 | — | — | — | — | — | ±6.9 |
| Example 1 | | | | | | | | | | | | |
| Comparative | 600 | 450 | 1050 | 100 | 150 | 145 | — | — | — | — | — | ±3.1 |
| Example 2 | | | | | | | | | | | | |

As described above, while the film thickness distribution exceeded 1% in Comparative Examples, the film thickness distribution was lower than 1% and it was found that favorable film thickness distribution was obtained in Examples 1 to 3.

Although embodiments of the present invention have been described above, it goes without saying that the present invention is not limited to the above-mentioned embodiments and various modifications can be made. Each embodiment is not limited to an independent form, and can be combined as much as technologically possible.

### REFERENCE SIGNS LIST

1, 2, 3, 4 deposition apparatus
10 vacuum chamber
20, 20A, 20B target
21, 21A, 21B backing plate
30 substrate holder
40 support stand
60, 60A, 60B power source
70 gas source
71 exhaust mechanism
90 substrate
101 chamber body
102 lid portion
300 central axis
301 rotating plate
302 rotating mechanism
310 central axis
311 substrate support
312 rotating mechanism

1. A deposition apparatus, comprising:
a first target;
a substrate holder that supports at least one substrate facing the first target, rotates around a first central axis, and is configured such that the substrate is rotatable around a second central axis deviated from the first central axis;
a vacuum chamber that houses the first target and the substrate holder;
a power source that supplies discharge power to the first target; and
a gas supply mechanism that supplies a discharge gas to the vacuum chamber, relational expressions of Ds+Dt≥H, A≥R, and H≥R being satisfied, Ds being a distance between the first central axis and the second central axis in a direction perpendicular to the first central axis, Dt being a distance between the first central axis and a center of the first target in a direction perpendicular to the first central axis, R being a radius of the first target, H being a distance between the first target and the substrate in a direction of the first central axis, A being an absolute value of a difference between Ds and Dt.

2. The deposition apparatus according to claim 1, further comprising
a second target juxtaposed with the first target in a direction perpendicular to the first central axis, wherein
relational expressions of Ds+Dt≥H′, A′≥R′, and H′≥R′ are satisfied, Dt′ being a distance between the first central axis and a center of the second target in a direction perpendicular to the first central axis, R′ being a radius of the second target, H′ being a distance between the second target and the substrate in the direction of the first central axis, A′ being an absolute value of a difference between Ds and Dt′.

3. The deposition apparatus according to claim 2, wherein
a sign of the difference between Ds and Dt is reversed from a sign of the difference between Ds and Dt′.

4. The deposition apparatus according to claim 2, wherein
the power source supplies electric power to the first target, the electric power being different from electric power supplied to the second target.

5. The deposition apparatus according to claim 2, wherein
one of a normal line to a surface of the substrate, a normal line to a surface of the first target, and a normal line to a surface of the second target intersects the first central axis.

6. A deposition apparatus, comprising:
a plurality of targets;
a substrate holder that supports at least one substrate facing the plurality of targets, rotates around a first central axis, and is configured such that the substrate is rotatable around a second central axis deviated from the first central axis;
a vacuum chamber that houses the plurality of targets and the substrate holder;
a power source that supplies discharge power to the plurality of targets; and
a gas supply mechanism that supplies a discharge gas to the vacuum chamber, wherein the plurality of targets is juxtaposed with each other in a direction perpendicular to the first central axis, and
relational expressions of Ds+Dt≥H, A≥R, and H≥R are satisfied, Ds being a distance between the first central axis and the second central axis in a direction perpendicular to the first central axis, Dt being a distance between the first central axis and a center of one of the plurality of targets in a direction perpendicular to the first central axis, R being a radius of the one target, H being a distance between the plurality of targets and the substrate in a direction of the first central axis, A being an absolute value of a difference between Ds and Dt.

7. A deposition method, comprising:
supporting at least one substrate on a substrate holder that is housed in a vacuum chamber and rotates around a first central axis, the substrate supported by the substrate holder rotating around a second central axis deviated from the first central axis;
supplying a discharge gas to the vacuum chamber;
supplying discharge power to a first target that faces the substrate holder and is housed in the vacuum chamber;
performing deposition on the substrate under a condition that relational expressions of Ds+Dt≥H, A≥R, and H≥R are satisfied, Ds being a distance between the first central axis and the second central axis in a direction perpendicular to the first central axis, Dt being a distance between the first central axis and a center of the first target in a direction perpendicular to the first central axis, R being a radius of the first target, H being a distance between the first target and the substrate in a direction of the first central axis, A being an absolute value of a difference between Ds and Dt.

8. The deposition method according to claim 7, wherein
juxtaposing a second target with the first target in a direction perpendicular to the first central axis in the vacuum chamber;
supplying discharge power to the second target; and
performing deposition on the substrate under a condition that relational expressions of Ds+Dt′≥H′, A′≥R′, and H′≥R′ are satisfied, Dt′ being a distance between the first central axis and a center of the second target in a direction perpendicular to the first central axis, R′ being a radius of the second target, H′ being a distance between the second target and the substrate in the direction of the first central axis, A′ being an absolute value of a difference between Ds and Dt′.
